(19) United States
(12) Patent Application Publication
(10) Pub. No.: US 2005/0161751 A1
(43) Pub. Date: Jul. 28, 2005

(54) MEMS device having compact actuator

(75) Inventors: Aaron Geisberger, Dallas, TX (US); Niladri Sarkar, Richardson, TX (US)

Correspondence Address: HAYNES AND BOONE, LLP, 901 MAIN STREET, SUITE 3100, DALLAS, TX, 75202, US

(73) Assignee: Zyvex Corporation, Richardson, TX (US)

(21) Appl. No.: 10/762,848

(22) Filed: Jan. 22, 2004

(51) Int. Cl. H01L 27/14

(52) U.S. Cl. 257/414

(57) ABSTRACT

A MEMS device including a plurality of actuator layers formed over a substrate and a bimorph actuator having a substantially serpentine pattern. The serpentine pattern is a staggered pattern having a plurality of static segments interlaced with a plurality of deformable segments. Each of the plurality of static segments has a static segment length and each of the plurality of deformable segments has a deformable segment length, wherein the deformable segment length is substantially different than the static segment length. At least a portion of each of the plurality of deformable segments and each of the plurality of static segments is defined from a common one of the plurality of actuator layers.

### BACKGROUND

The present disclosure relates generally to MEMS devices and, more specifically, to a MEMS device having an altered actuator, a method of manufacturing the device and a system incorporating the device.

MEMS devices may include a first sacrificial layer, a first polysilicon layer, a second sacrificial layer, a second polysilicon layer and a metal layer successively stacked over a substrate. Simple MEMS actuators may be defined in the second polysilicon layer and the metal layer, and are often “released” from the substrate by removing a portion of the second sacrificial layer underlying the actuator. More complex actuators and other MEMS devices may include components defined in the first and second polysilicon layers, and some devices may include more than two polysilicon layers.

A bimorph actuator is one type of MEMS actuator that can be fabricated from the above-described layers. For example, a MEMS bimorph actuator may consist of an actuating member defined by etching or otherwise patterning the topmost polysilicon layer and the metal layer. Thermal and/or electrical deflection may configure the MEMS actuator to exhibit desired physical orientations and/or electrical characteristics that are dependent upon the degree of deflection. However, the amount of deflection and/or attainable range of electrical characteristics are becoming insufficient as device scaling continues and as device performance requirements steadily increase.

Accordingly, what is needed in the art is a MEMS device and method of manufacture thereof that addresses the above-discussed issues.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1A illustrates a sectional view of one embodiment of a MEMS device constructed according to aspects of the present disclosure.

FIG. 1B illustrates a sectional view of another embodiment of a MEMS device during an intermediate stage of manufacture according to aspects of the present disclosure.

FIG. 1C illustrates a sectional view of the MEMS device shown in FIG. 1B in a subsequent stage of manufacture according to aspects of the present disclosure.

FIG. 2 illustrates a perspective view of a portion of one embodiment of a MEMS actuator constructed according to aspects of the present disclosure.

FIG. 3 illustrates a perspective view of a portion of another embodiment of a MEMS actuator constructed according to aspects of the present disclosure.

FIG. 4 illustrates a perspective view of a portion of another embodiment of a MEMS actuator constructed according to aspects of the present disclosure.

FIG. 5 illustrates a perspective view of a portion of one embodiment of an actuated MEMS device constructed according to aspects of the present disclosure.

FIG. 6 illustrates a perspective view of another embodiment of an actuated MEMS device constructed according to aspects of the present disclosure.

FIG. 7 illustrates a perspective view of another embodiment of an actuated MEMS device constructed according to aspects of the present disclosure.

FIG. 8 illustrates a perspective view of another embodiment of an actuated MEMS device constructed according to aspects of the present disclosure.

FIG. 9 illustrates a perspective view of another embodiment of an actuated MEMS device constructed according to aspects of the present disclosure.

FIG. 10 illustrates a perspective view of another embodiment of an actuated MEMS device constructed according to aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over, on or coupled to a second feature in the description that follows may include embodiments in which the first and second features are in direct contact, and may also include embodiments in which additional features interpose the first and second features, such that the first and second features may not be in direct contact.

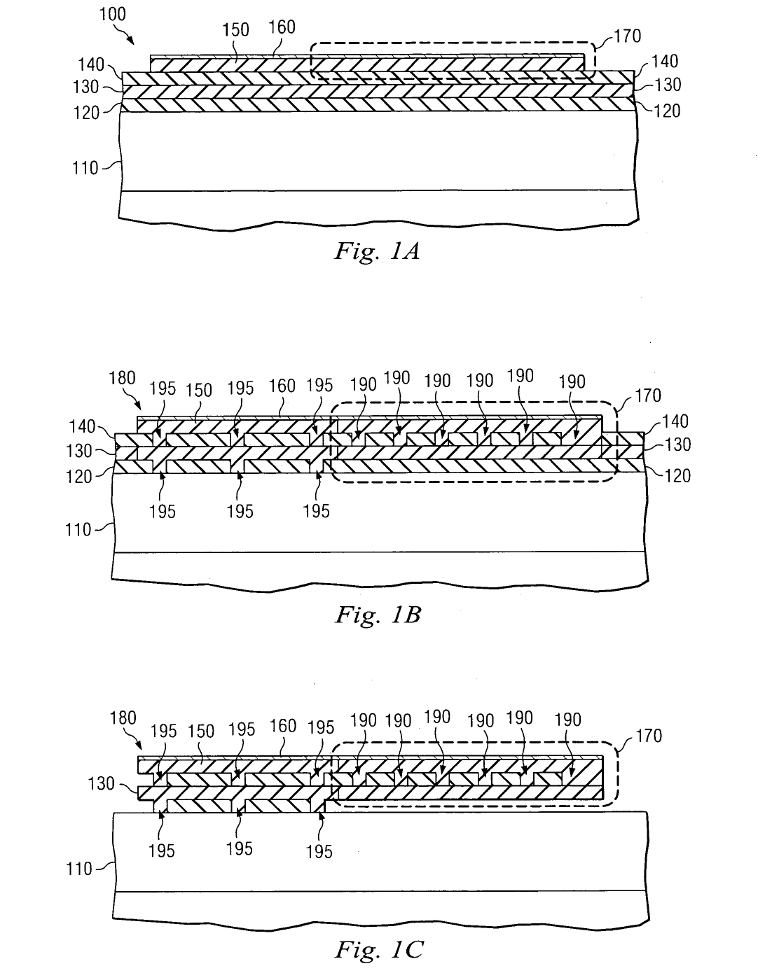

Referring to FIG. 1, illustrated is a sectional view of one embodiment of a MEMS device 100 constructed according to aspects of the present disclosure. In one embodiment, the MEMS device 110 may have feature dimensions (e.g., patterned line widths) that are less than about 50 microns. In another embodiment, the feature dimensions may be less than about 25 microns. The MEMS device 110 may also be a NEMS device, such as those having feature dimensions less than about 1000 nm. Accordingly, descriptions herein pertaining to MEMS devices are applicable and/or readily adaptable to NEMS devices, such that embodiments herein regarding MEMS devices also contemplate NEMS devices.

The MEMS device 100 may include or be formed on or over a substrate 110, which may comprise a bottom-most layer or region of the device 100 or a component of another device to which the MEMS device 100 may be bonded or otherwise coupled. The substrate 110 may comprise at least a portion of a silicon-on-insulator (SOI) substrate.

In the illustrated embodiment, the MEMS device 100 is defined from a stack of layers over the substrate 110 successively including a sacrificial layer 120, an actuator layer 130, a sacrificial layer 140, and additional actuator layers 150 and 160. In one embodiment, the sacrificial layers 120, 140 comprise silicon dioxide, the actuator layers 130 and 150 comprise polysilicon, and the actuator layer 160 comprises gold and/or another metal or metal alloy. Each of the layers 120-160 may be formed by conventional or future-developed processes, and may have individual thicknesses ranging between about 100 nm and about 10,000 nm. The layers 120-160 may also have other thicknesses and comprise other materials within the scope of the present disclosure. An actuator 170 may be etched, patterned, or otherwise defined from the actuator layers 150 and 160, as indicated in FIG. 1. However, the actuator 170 may also be defined from the actuator layers 130, 150, and 160, or from additional and/or alternative layers. The layers from which the actuator 170 is defined may not have common coefficients of thermal expansion, such that the actuator 170 (and similar examples described below) may be a bimorph actuator.

The actuator layer 150 may comprise a first material having a first coefficient of thermal expansion and the actuator layer 160 may comprise a second material having a second coefficient of thermal expansion, wherein the first and second coefficients of thermal expansion are different. For example, the first coefficient of thermal expansion may be greater than or less than the second coefficient of thermal expansion. In one embodiment, the first coefficient of thermal expansion may be about 3.0 ppm/deg and the second coefficient of thermal expansion may be about 14.0 ppm/deg. In another embodiment, the first coefficient of thermal expansion may be at least about 450% less than the second coefficient of thermal expansion. The actuator layer 150 may also comprise a material having a different coefficient of thermal expansion than the actuator layer 130.

Referring to FIG. 1B, illustrated is a sectional view of another embodiment of a MEMS device 180 constructed according to aspects of the present disclosure. The MEMS device 180 may be substantially similar to the MEMS device 100 shown in FIG. 1A. However, the MEMS device 180 may employ the actuator layer 130 to reinforce the actuator 170 or to provide multidirectional current paths, as in embodiments described below. For example, vias or other openings 190 (hereafter collectively referred to as vias) may be etched or otherwise patterned in the sacrificial layer 140 prior to depositing the actuator layer 150 over the sacrificial layer 140. When the actuator layer 150 is subsequently formed over the sacrificial layer 140, the vias 510 are substantially filled with the material forming the actuator layer 150.

Referring to FIG. 1C, illustrated is a sectional view of the MEMS device 180 shown in FIG. 1B after undergoing a release process. During the release process, all or a portion of the MEMS device 180 may be dip-etched in hydrofluoric acid or another etching chemistry to substantially remove the sacrificial layers 120, 140. Consequently, the actuator 170 may comprise portions of the actuator layer 130 in addition to portions of the actuator layers 150, 160. As similarly described above, the actuator layers 130, 150, 160 may have varying coefficients of thermal expansion, such that the actuator 170 may be a bimorph actuator. As also shown in FIGS. 1B and 1C, additional vias 195 may be formed to anchor the MEMS device 180 to the substrate 110. Moreover, the released position of the actuator 170 is not limited to the orientation shown in FIG. 1C. For example, inherent stresses may accumulate during the fabrication of the actuator 170 prior to the release process, such that upon the completion of the release process the actuator 170 may be skewed away or towards the substrate 110.

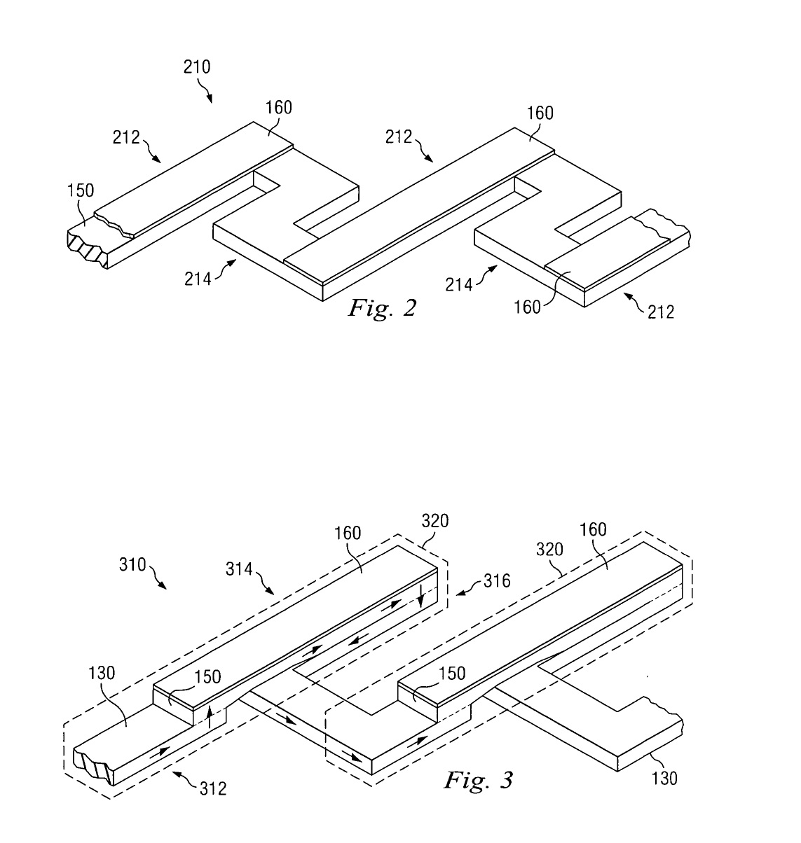

Referring to FIG. 2 with continued reference to FIG. 1A, illustrated is a perspective of a portion of one embodiment of an actuator 210 constructed according to aspects of the present disclosure. The actuator 210 may be similar in composition and manufacture to the actuator 170 shown in FIG. 1A. The actuator 210 may be defined from the first and second actuator layers 150, 160 of FIG. 1A, such as by etching or otherwise patterning. For example, in the embodiment shown in FIG. 2, the actuator 210 has a substantially serpentine shape. However, only portions of the actuator 210 may be defined from both of the actuator layers 150, 160. That is, the actuator 170 may comprise a plurality of deformable segments 212 coupled end-to-end by interposing static segments 214, wherein the deformable segments 212 include portions of the actuator layers 150, 160, and the static segments 214 include portions of the actuator layer 150 but not of the actuator layer 160.

The deformable segments 212 and/or the static segments 214 may be rectilinear, curvilinear, or otherwise patterned as necessary for interconnection and desired path of travel, deflection, and/or rotation. The segments 212, 214 may also collectively form a staggered serpentine configuration. For example, the deformable segments 212 may be longer or shorter than the static segments 214, such that the ends of adjacent deformable segments 212 may be offset in a direction substantially parallel to longitudinal axes of the deformable segments 212.

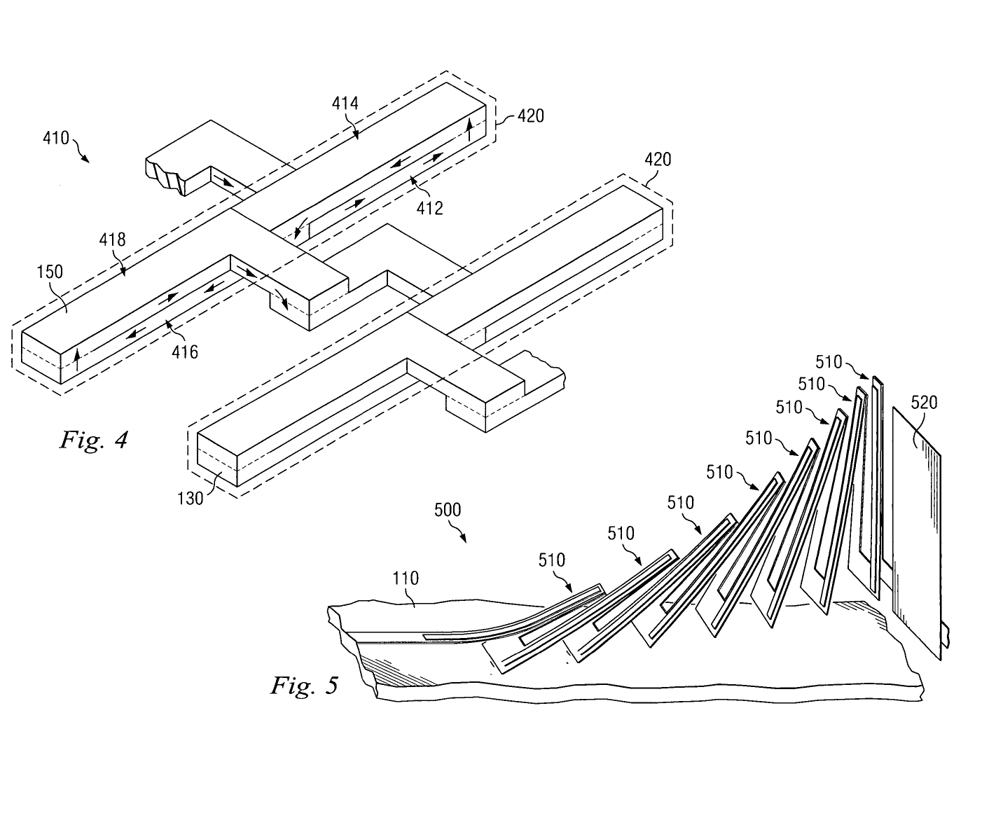

Referring to FIG. 3 with continued reference to FIG. 1C, illustrated is a perspective view of a portion of another embodiment of an actuator 310 constructed according to aspects of the present disclosure. The actuator 310 may be substantially similar in composition and manufacture to the actuator 170 shown in FIG. 1C. The actuator 310 may be defined from the actuator layers 130, 150, and 160 of FIG. 1C, such as by etching or otherwise patterning. In the embodiment shown in FIG. 3, the actuator 310 has a substantially helical shape. That is, the actuator 310 includes laterally disposed segments 320, each of which may be considered a winding, or may employ 3 or 4 turns in current path.

A convenient convention in describing the layout or pattern of actuators herein is to trace current flow through the actuators. Thus, in the illustrated embodiment, current may propagate through an actuator segment 320 beginning from a portion 312 defined from the semiconductor layer 130, then through a portion 314 defined from one or both of the actuator layers 150 and 160, then back through another portion 316 defined from the actuator layer 130 in a physical direction opposite to the physical direction of current in the actuator portion 312, as shown by arrows in FIG. 3. A first end of the portion 314 is electrically coupled to the portion 312, and a second end of the portion 314 is electrically coupled to the portion 316, although a substantial length of the portion 314 is electrically isolated from the portion 316, such as by a portion of the sacrificial layer 140, which may become an air gap during manufacturing. The actuator 310 may comprise any number of segments 320, each of which may comprise portions 312, 314, 316. Moreover, the segments 320 may each be rectilinear, curvilinear, a combination thereof, or otherwise patterned as necessary for interconnection and desired path of travel, deflection, and/or rotation.

Referring to FIG. 4 with continued reference to FIG. 1C, illustrated is a perspective view of another embodiment of an actuator 410 constructed according to aspects of the present disclosure. The actuator 410 may be substantially similar in composition and manufacture to the actuator 170 shown in FIG. 1C. The actuator 410 may be defined from the actuator layers 130, 150, and 160 of FIG. 1, such as by etching or otherwise patterning, or from the actuator layers 130 and 150, as in the illustrated embodiment.

In the embodiment shown in FIG. 4, the actuator 410 includes segments 420 each having a substantially figure-8 shaped configuration. That is, each of the laterally disposed segments 420 include 4 portions forming a figure-8 shape. For example, current may propagate through an actuator segment 420 beginning from a portion 412 defined from the actuator layer 130, then through a portion 414 defined from one or both of the actuator layers 150 and 160, then through a portion 416 defined from the actuator layer 130, and then through a portion 418 defined from one or both of the actuator layers 150 and 160. A first end of the portion 414 is electrically coupled to the portion 412, and a second end of the portion 414 is electrically coupled to the portion 416, although a substantial length of the portion 414 is electrically isolated from the portion 412, such as by a portion of the sacrificial layer 140, an air gap, and/or an insulating material. Similarly, a first end of the portion 416 is electrically coupled to the portion 414, and a second end of the portion 416 is electrically coupled to the portion 418, although a substantial length of the portion 416 is electrically isolated from the portion 418. The actuator 410 may comprise any number of segments 420, each of which may comprise portions 412, 414, 416, 418. Moreover, the segments 420 may each be rectilinear, curvilinear, a combination thereof, or otherwise patterned as necessary for interconnection and desired path of travel, deflection, and/or rotation.

The actuators 210, 310, and 410 may be employed, separately or in combination, to form MEMS devices of various configurations. For example, referring to FIG. 5, illustrated is a perspective view of one embodiment of a MEMS device 500 constructed according to aspects of the present disclosure. The MEMS device 500 is illustrated in a deflected state, wherein exposure to thermal and/or electrical energy has caused actuator segments 510 to deflect. The deflection of the segments 510 has caused the translation and/or rotation of a payload 520 away from an as-built, pre-deflection state in which the segments 510 and the payload 520 may be substantially parallel to the substrate 110.

The MEMS device 500 may be classified as a helical, staggered, rectilinear, partially-metallized device. That is, the MEMS device 500 may be classified as helical because it employs actuator segments 510 that are substantially similar to the actuator segments 320 shown in FIG. 3. Ends of each or several of the segments 510 are offset from ends of adjacent segments 510 in a direction 520, such that the segments 510 are also staggered. The direction 520 is substantially parallel to longitudinal axes of the segments 510 in a pre-deflection state. The segments 510 are also patterned from actuator layers in substantially straight, non-curved, rectangular, or otherwise rectilinear (herein collectively referred to as rectilinear) segments. Moreover, only portions of the segments 510 include a metallic actuator layer (such as the actuator layer 160 discussed above), such that the MEMS device 500 is only partially metallized.

The payload 520 may be defined from one or both of the actuator layers 150 and 160 shown in FIG. 1C. Thus, the payload 520 may be integral to or otherwise coupled to opposing ones of the actuator segments 510. The payload 520 may comprise a mirrored surface and/or a grating surface, such as when the MEMS device 500 is employed as a switch and/or a filter in an optical system. The payload 520 may also comprise an electrically conductive plate or layer, such as when the MEMS device 500 is employed as a capacitive element or a portion thereof. The payload 520 may also comprise a spiral-shaped trace, such as when the MEMS device 500 is employed as an inductive element or a portion thereof.

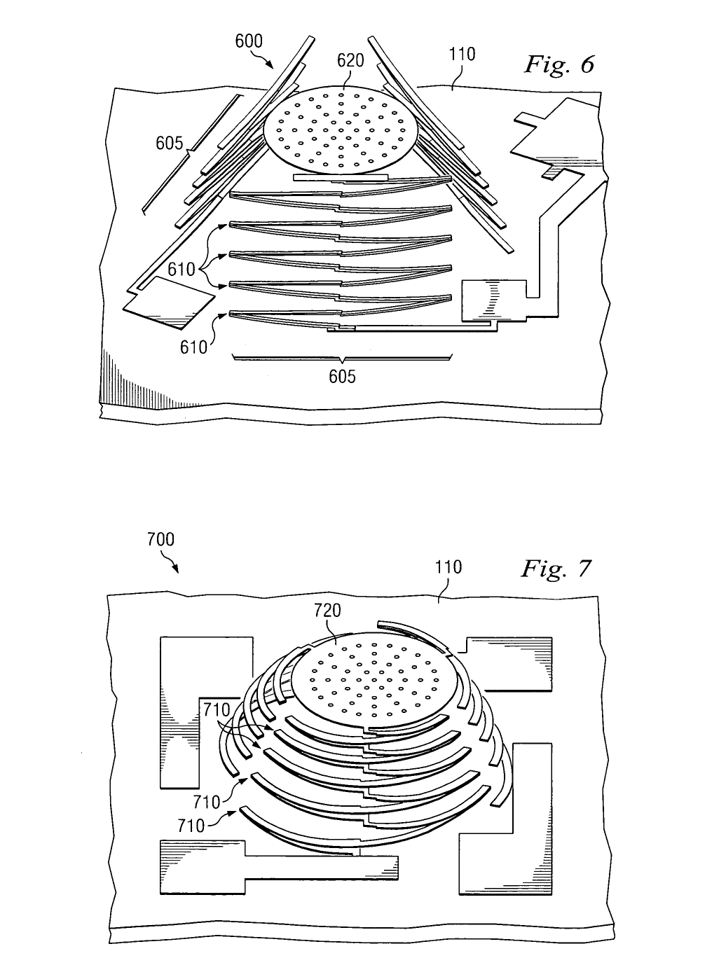

Referring to FIG. 6, illustrated is a perspective view of another embodiment of a MEMS device 600 constructed according to aspects of the present disclosure. The MEMS device 600 includes 3 groups 605 of actuator segments 610. The MEMS device 600 is illustrated in a deflected state, wherein exposure to thermal and/or electrical energy has caused actuator segments 610 to deflect. The deflection of the segments 610 has caused the translation of a payload 620 away from an as-built, pre-deflection state in which the segments 610 and the payload 620 are substantially parallel to the substrate 110.

The MEMS device 600 may be classified as a figure-8 shaped, symmetric, rectilinear, partially-metallized device. The MEMS device 600 may be classified as figure-8 shaped because it employs actuator segments 610 that are substantially similar to the actuator segments 420 shown in FIG. 4. Ends of each or several of the segments 610 are not offset from, or are substantially aligned with, ends of adjacent segments 610, such that the segments 610 are also symmetric. The segments 610 are also patterned from actuator layers in substantially rectilinear segments. Moreover, only portions of the segments 610 include a metallic actuator layer (such as the actuator layer 160 discussed above), such that the MEMS device 600 is only partially metallized.

Referring to FIG. 7, illustrated is a perspective view of one embodiment of a MEMS device 700 constructed according to aspects of the present disclosure. The MEMS device 700 includes 4 groups of actuator segments 710. The MEMS device 700 is illustrated in a deflected state, wherein exposure to thermal and/or electrical energy has caused actuator segments 710 to deflect. The deflection of the segments 710 has caused the translation of a payload 720 away from an as-built, pre-deflection state in which the segments 710 and the payload 720 are substantially parallel to the substrate 110.

The MEMS device 700 may be classified as a figure-8 shaped, symmetric, curvilinear, partially-metallized device. That is, the MEMS device 700 may be classified as figure-8 shaped because it employs actuator segments 710 that are substantially similar to the actuator segments 420 shown in FIG. 4. Ends of each or several of the segments 710 are not offset from, or are substantially aligned with, ends of adjacent segments 710, such that the segments 710 are also symmetric. The segments 710 are also patterned from actuator layers in substantially curvilinear segments, or arcs. Moreover, only portions of the segments 710 include a metallic actuator layer (such as the actuator layer 160 discussed above), such that the MEMS device 700 is only partially metallized.

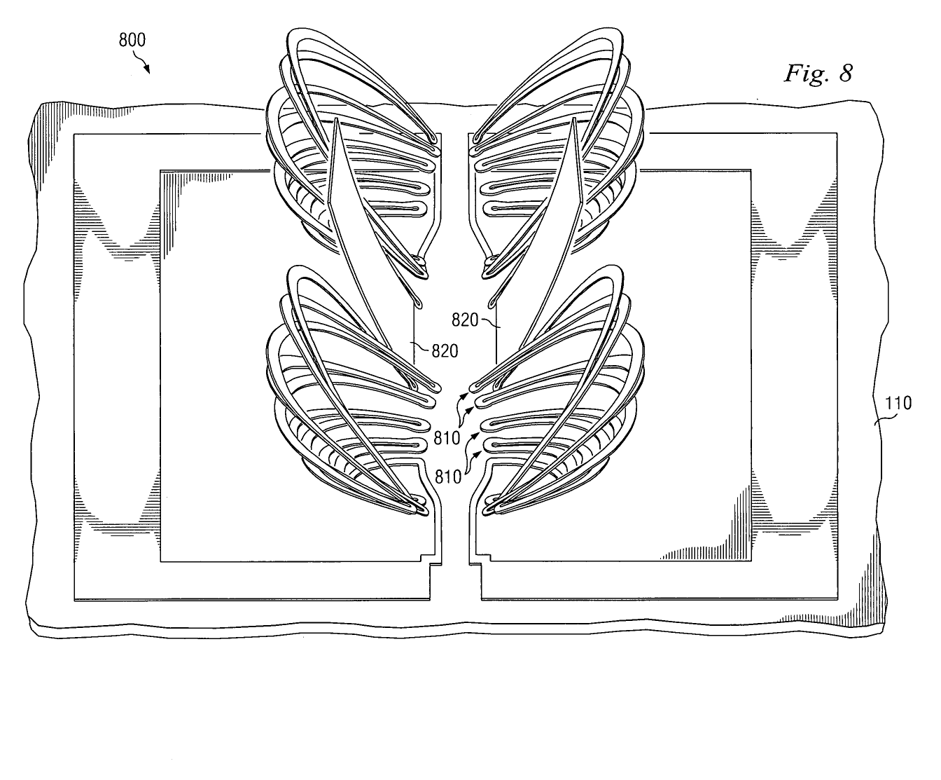

Referring to FIG. 8, illustrated is a perspective view of one embodiment of a MEMS device 800 constructed according to aspects of the present disclosure. The MEMS device 800 includes 4 groups of actuator segments 810 employed to simultaneously or independently actuate 2 payloads 820. The MEMS device 800 is illustrated in a deflected state, wherein exposure to thermal and/or electrical energy has caused actuator segments 810 to deflect. The deflection of the segments 810 has caused the rotation and/or translation of a payload 820 away from an as-built, pre-deflection state in which the segments 810 and the payload 820 are substantially parallel to the substrate 110.

The MEMS device 800 may be classified as a serpentine, symmetric, curvilinear, substantially-metallized device. That is, the MEMS device 800 may be classified as serpentine because it employs actuator segments 810 that are substantially similar to the actuator segments 220 shown in FIG. 2. Ends of each or several of the segments 810 are not offset from, or are substantially aligned with, ends of adjacent segments 810, such that the segments 810 are also symmetric. The segments 810 are also patterned from actuator layers in substantially curvilinear segments, or arcs. Moreover, substantial portions of the segments 810 include a metallic actuator layer, such that the MEMS device 800 is substantially or completely metallized. The metallic actuator layer may be substantially similar in composition and manufacture to the actuator layer 160 shown in FIG. 1C. Moreover, each or several of the segments 810 may be substantially similar to the structure shown in FIG. 1C.

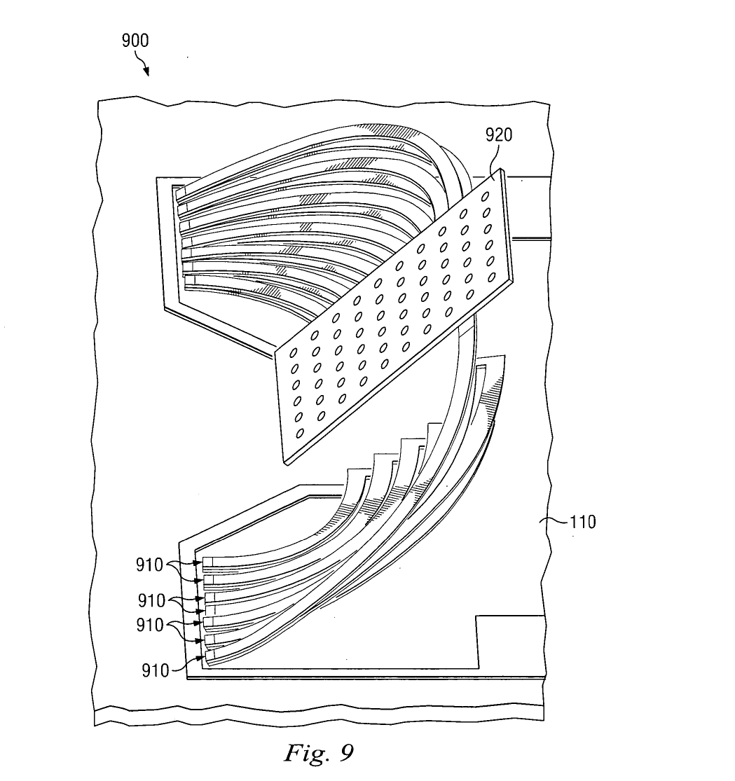

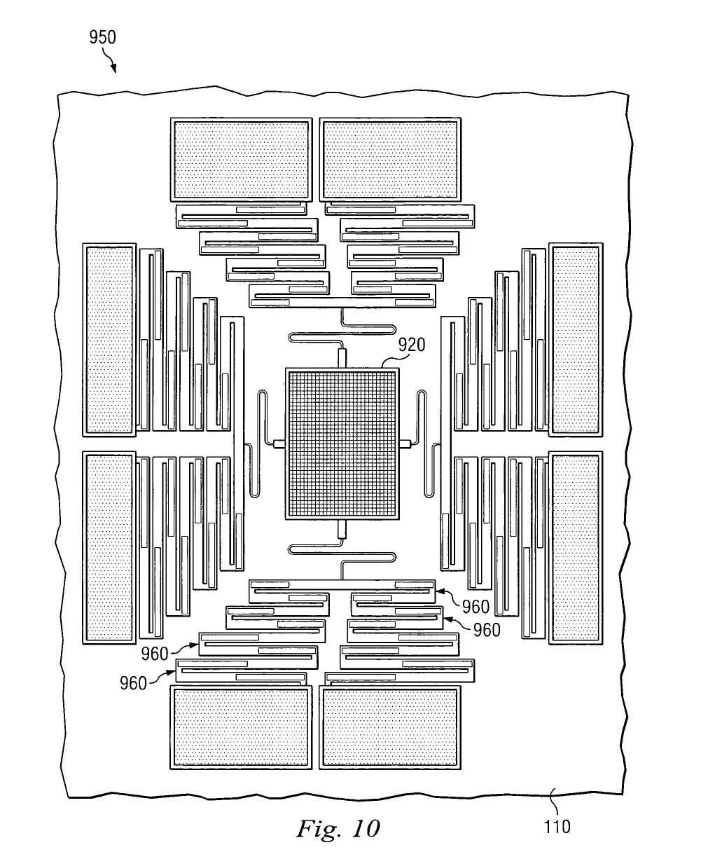

Referring to FIG. 9, illustrated is a perspective view of one embodiment of a MEMS device 900 constructed according to aspects of the present disclosure. The MEMS device 900 is illustrated in a deflected state, wherein exposure to thermal and/or electrical energy has caused actuator segments 910 to deflect. The deflection of the segments 910 has caused the rotation and/or translation of a payload 920 away from an as-built, pre-deflection state in which the segments 910 and the payload 920 are substantially parallel to the substrate 110.

The MEMS device 900 may be classified as a helical, symmetric, curvilinear, partially-metallized device. That is, the MEMS device 900 may be classified as helical because it employs actuator segments 910 that are substantially similar to the actuator segments 320 shown in FIG. 3. Ends of each or several of the segments 910 are not offset from, or are substantially aligned with, ends of adjacent segments 910, such that the segments 910 are also symmetric. The segments 910 are also patterned from actuator layers in substantially curvilinear segments, or arcs. Moreover, only portions of the segments 910 include a metallic actuator layer (such as the actuator layer 160 discussed above), such that the MEMS device 900 is only partially metallized.

Referring to FIG. 10, illustrated is a perspective view of one embodiment of a MEMS device 950 constructed according to aspects of the present disclosure. The MEMS device 950 includes 4 groups of actuator segments 960 employed to actuate a payload 970. The MEMS device 950 is illustrated in a deflected state, wherein exposure to thermal and/or electrical energy has caused actuator segments 960 to deflect. The deflection of the segments 960 has caused the translation of a payload 970 away from an as-built, pre-deflection state in which the segments 960 and the payload 970 are substantially parallel to the substrate 110.

The MEMS device 950 may be classified as a serpentine, symmetric, rectilinear, partially-metallized device. That is, the MEMS device 950 may be classified as serpentine because it employs actuator segments 960 that are substantially similar to the actuator segments 220 shown in FIG. 2. Ends of each or several of the segments 960 are not offset from, or are substantially aligned with, ends of adjacent segments 960, such that the segments 960 are also symmetric. The segments 960 are also patterned from actuator layers in substantially rectilinear segments. Moreover, only portions of the segments 960 include a metallic actuator layer (such as the actuator layer 160 discussed above), such that the MEMS device 950 is only partially metallized.

As previously mentioned, each of the devices 500, 600, 700, 800, 900, 950 described above may be deformed or otherwise actuated in response to exposure to thermal energy. Possible sources for such thermal energy may include a hot plate, a furnace, an oven, a laser and/or other sources. In one embodiment, a current source is coupled to contacts for delivering electrical current through the actuator segments. In such embodiments, the actuator segments and/or other portions of the MEMS devices may comprise material that is thermally resistive or dissipates heat in response to electrical current. Accordingly, the source of the deforming thermal energy may be the actuator segments themselves, such as through ohmic heating.

The exposure to thermal energy described above may be more severe than the thermal energy conventionally employed to actuate a typical bimorph MEMS actuator. Conventionally, a MEMS bimorph actuator is exposed to sufficient thermal energy to elastically deflect the actuator, such that when the thermal energy is removed the actuator returns to an as-built or as-released position. However, MEMS devices constructed according to aspects of the present disclosure may also be exposed to sufficient thermal energy to cause plastic deformation, such that when the plastically deforming thermal energy is removed the actuator segments maintain (or are deformed into) some degree of deflection.

For example, a MEMS device constructed according to aspects of the present disclosure may be exposed to 2 one-second electrical pulses at about 12 volts, such that the actuator segments may be plastically deformed to orient a payload in a position that is angularly offset about 45° relative to the substrate on which the MEMS device is formed. In another example, a MEMS device constructed according to aspects of the present disclosure may be exposed to 2 one-second electrical pulses at about 14 volts to sufficiently plastically deform it so as to orient a payload in a position that is angularly offset about 60° to about 65° relative to the substrate. Similarly, a MEMS device constructed according to aspects of the present disclosure may be exposed to a single, one-second electrical pulse at about 16 volts, such that a payload is oriented at about 90° relative to the substrate.

The deflection and/or deformation of a MEMS device constructed according to aspects of the present disclosure may be employed to configure the MEMS device to have a desired electrical characteristic in a biased and/or unbiased position. For example, the actuator segments thereof may be plastically deformed into a position that configures the MEMS device to exhibit a desired inductance, capacitance or other characteristic. The actuator segments may also be deformed into a position that configures a payload in a desired orientation, such as in embodiments in which the payload comprises a mirrored surface or a periodic structure. After plastic deformation, the actuator segments may be further actuated by exposure to thermal energy to elastically deflect the actuator segments to a biased position temporarily until the MEMS device is removed from the exposure to thermal energy. Such elastically deforming thermal energy may emanate from the same source employed during the plastic deformation, although possibly to a lesser degree.

Thus, the present disclosure provides a MEMS device including a plurality of actuator layers formed over a substrate and a bimorph actuator having a substantially serpentine pattern. The serpentine pattern is a staggered pattern having a plurality of static segments interlaced with a plurality of deformable segments. Each of the plurality of static segments has a static segment length and each of the plurality of deformable segments has a deformable segment length, wherein the deformable segment length is substantially different than the static segment length. At least a portion of each of the plurality of deformable segments and each of the plurality of static segments is defined from a common one of the plurality of actuator layers.

Another embodiment of a MEMS device constructed according to aspects of the present disclosure includes a plurality of actuator layers formed over a substrate and a bimorph actuator. The bimorph actuator includes a plurality of segments defined from the plurality of actuator layers, wherein each of the plurality of segments includes a number of turns and is laterally offset from neighboring ones of the plurality of segments, the plurality of segments thereby forming a helical configuration.

Another embodiment of a MEMS device constructed according to aspects of the present disclosure includes a plurality of actuator layers formed over a substrate and a bimorph actuator. The bimorph actuator includes a plurality of segments defined from the plurality of actuator layers, wherein each of the plurality of segments has a substantially figure-8 shaped configuration.

Although embodiments of the present disclosure have been described in detail, those skilled in the art should understand that they can make various changes, substitutions and alterations herein without departing from the spirit and scope of the present disclosure.

1. A MEMS device, comprising:
a plurality of actuator layers formed over a substrate;
a bimorph actuator having a substantially serpentine pattern, wherein the serpentine pattern is a staggered pattern having a plurality of static segments interlaced with a plurality of deformable segments, each of the plurality of static segments having a static segment length and each of the plurality of deformable segments having a deformable segment length, wherein the deformable segment length is substantially different than the static segment length, and wherein at least a portion of each of the plurality of deformable segments and each of the plurality of static segments is defined from a common one of the plurality of actuator layers.

2. The device of claim 1 wherein each of the plurality of static segments is defined from a first one of the plurality of actuator layers and each of the plurality of deformable segments is defined from the first one and an adjacent second one of the plurality of actuator layers.

3. The device of claim 1 wherein the first and second ones of the plurality of actuator layers have different coefficients of thermal expansion.

4. The device of claim 1 further comprising a payload coupled to the bimorph actuator and movable between first and second orientations in response to exposure of the bimorph actuator to one of thermal energy and electrical energy.

5. The device of claim 1 wherein at least one of the plurality of deformable segments and the plurality of static segments has a substantially rectilinear pattern.

6. The device of claim 1 wherein at least one of the plurality of deformable segments and the plurality of static segments has a substantially curvilinear pattern.

7. A MEMS device, comprising:
a plurality of actuator layers formed over a substrate;
a bimorph actuator comprising a plurality of segments defined from the plurality of actuator layers and each including a number of turns and laterally offset from neighboring ones of the plurality of segments, the plurality of segments thereby forming a helical configuration.

8. The device of claim 7 wherein a first one of the plurality of segments includes:
a first portion defined from a first one of the plurality of actuator layers, wherein a first end of the first portion is electrically connected to a second one of the plurality of segments laterally disposed from the first one of the plurality of segments;
a second portion defined from a second one of the plurality of actuator layers, wherein a first end of the second portion end is electrically connected to a second end of the first portion; and
a third portion defined from the first one of the plurality of actuator layers, wherein a first end of the third portion is electrically connected to a second end of the second portion, and wherein a second end of the third portion is electrically connected to a third one of the plurality of segments laterally disposed from the first one of the plurality of segments.

9. The device of claim 8 wherein the second portion is defined from the second one of the plurality of actuator layers and an adjacent third one of the plurality of actuator layers.

10. The device of claim 7 further comprising a payload coupled to the bimorph actuator and movable between first and second orientations in response to exposure of the bimorph actuator to one of thermal energy and electrical energy.

11. The device of claim 7 wherein at least one of the plurality of segments has a substantially rectilinear pattern.

12. The device of claim 7 wherein at least one of the plurality of segments has a substantially curvilinear pattern.

13. A MEMS device, comprising:
a plurality of actuator layers formed over a substrate;
a bimorph actuator comprising a plurality of segments defined from the plurality of actuator layers and each having a substantially figure-8 shaped configuration.

14. The device of claim 13 wherein a first one of the plurality of segments includes:
a first portion defined from a first one of the plurality of actuator layers, wherein a first end of the first portion is electrically connected to a second one of the plurality of segments laterally disposed from the first one of the plurality of segments;
a second portion defined from a second one of the plurality of actuator layers, wherein a first end of the second portion end is electrically connected to a second end of the first portion;
a third portion defined from the first one of the plurality of actuator layers, wherein a first end of the third portion is electrically connected to a second end of the second portion; and
a fourth portion defined from the second one of the plurality of actuator layers, wherein a first end of the fourth portion is electrically connected to a second end of the third portion, and wherein a second end of the fourth portion is electrically connected to a third one of the plurality of segments laterally disposed from the first one of the plurality of segments.

15. The device of claim 14 wherein the second and fourth portions are defined from the second one of the plurality of actuator layers and an adjacent third one of the plurality of actuator layers.

16. The device of claim 13 further comprising a payload coupled to the bimorph actuator and movable between first and second orientations in response to exposure of the bimorph actuator to one of thermal energy and electrical energy.

17. The device of claim 13 wherein at least one of the plurality of segments has a substantially rectilinear pattern.

18. The device of claim 13 wherein at least one of the plurality of segments has a substantially curvilinear pattern.

19. The device of claim 13 wherein the actuator has a patterned line width of less than about 50 microns.

20. The device of claim 13 wherein the actuator has a patterned line width of less than about 1000 nm.
